(19) United States
(12) Patent Application Publication
(10) Pub. No.: US 2023/0422479 A1
(43) Pub. Date: Dec. 28, 2023

(54) SEMICONDUCTOR DEVICE

(71) Applicant: Samsung Electronics Co., Ltd., Suwon-si (KR)

(72) Inventors: Jeesun Lee, Suwon-si (KR); Junsoo Kim, Suwon-si (KR); Daehyun Moon, Suwon-si (KR); Namhyun Lee, Suwon-si (KR); Seonhaeng Lee, Suwon-si (KR); Sungho Jang, Suwon-si (KR); Joohyun Jeon, Suwon-si (KR); Joon Han, Suwon-si (KR)

(73) Assignee: Samsung Electronics Co., Ltd., Suwon-si (KR)

(21) Appl. No.: 18/133,964

(22) Filed: Apr. 12, 2023

(30) Foreign Application Priority Data
Jun. 28, 2022 (KR) 10-2022-0078640

(51) Int. Cl. H10B 12/00

(52) U.S. Cl. CPC H10B 12/315; H10B 12/34; H10B 12/482

(57) ABSTRACT

A semiconductor device includes a first active pattern included in an upper portion of a substrate in a memory cell region, and having an isolated shape extending so that a direction oblique to a first direction is a major axis direction of the first active pattern. A first device isolation pattern provided inside a first trench included in the substrate, and covering a side wall of the first active pattern is provided. A first gate structure is provided inside a gate trench extending in the first direction on upper portions of the first active pattern and the first device isolation pattern. A barrier impurity region is selectively formed only on surfaces of both side walls of a major axis of the first active pattern. First and second impurity regions are provided on the upper portion of the first active pattern adjacent to both sides of the first gate structure.

### CROSS-REFERENCE TO RELATED APPLICATION

This application claims priority under 35 USC § 119 to Korean Patent Application No. 10-2022-0078640 filed on Jun. 28, 2022 in the Korean Intellectual Property Office (KIPO), the entire disclosure of which is incorporated herein by reference.

### BACKGROUND

### 1. Field

Embodiments relate to a semiconductor device. More particularly, embodiments of relate to a DRAM device.

### 2. Description of the Related Art

A unit cell of a DRAM device may include a recessed channel transistor and a capacitor. The recessed channel transistor may include an active pattern, and a gate structure buried in a device isolation pattern. As the DRAM device is highly integrated, a gap between gate structures may be reduced. Accordingly, disturbance of the gate structure may cause a malfunction of the recessed channel transistor and an operation failure of the unit cell.

### SUMMARY

Example embodiments provide a semiconductor device having excellent operating characteristics.

According to example embodiments, there is provided a semiconductor device. The semiconductor device includes a substrate extending in a first direction and a second direction perpendicular to the first direction, a first active pattern included in an upper portion of the substrate in a memory cell region, and having an isolated shape extending in a third direction that is oblique to the first direction, the third direction being a major axis direction of the first active pattern. A first device isolation pattern provided inside a first trench included in the substrate in the memory cell region, and covering a side wall of the first active pattern is provided. A first gate structure is provided inside a gate trench extending in the first direction on upper portions of the first active pattern and the first device isolation pattern. A barrier impurity region is selectively formed only on surfaces of both side walls of the major axis of the first active pattern. First and second impurity regions are provided on the upper portion of the first active pattern that is adjacent to both sides of the first gate structure.

According to example embodiments, there is provided a semiconductor device. The semiconductor device includes a substrate including a memory cell region, a core-peripheral region, and a boundary region between the memory cell region and the core-peripheral region. A first active pattern and a first device isolation pattern are provided on an upper portion of the substrate in the memory cell region. A second device isolation pattern filling a second trench included in the substrate in the boundary region between the memory cell region and the core-peripheral region is provided. A third device isolation pattern filling a third trench included in the substrate in the core-peripheral region is provided. A first gate structure is provided inside a gate trench extending in a first direction on upper portions of the first active pattern and the first device isolation pattern. A barrier impurity region is selectively formed only on surfaces of both side walls of a major axis of the first active pattern. First and second impurity regions are provided on the upper portion of the first active pattern that is adjacent to both sides of the first gate structure. A bottom surface of the second trench has a step shape without being flat.

According to example embodiments, there is provided a semiconductor device. The semiconductor device includes a substrate including a memory cell region, a core-peripheral region, and a boundary region between the memory cell region and the core-peripheral region. A first active pattern and a first device isolation pattern are provided on an upper portion of the substrate in the memory cell region. A second device isolation pattern filling a second trench included in the substrate in the boundary region between the memory cell region and the core-peripheral region is provided. A third device isolation pattern filling a third trench included in the substrate in the core-peripheral region is provided. A first gate structure is provided inside a gate trench extending in a first direction on upper portions of the first active pattern and the first device isolation pattern. A barrier impurity region is selectively formed only on surfaces of both side walls of a major axis of the first active pattern, and doped with silicon germanium or fluorine. First and second impurity regions are provided on the upper portion of the first active pattern that is adjacent to both sides of the first gate structure. A bit line structure electrically connected to the first impurity region is provided. A capacitor electrically connected to the second impurity region is provided.

According to the semiconductor device of exemplary embodiments, the barrier impurity region may be selectively formed only on the surfaces of the both side walls of the major axis of the first active pattern. Since the barrier impurity region is provided, movement and leakage of charges from the first active pattern under the second impurity region to a lower portion of a bottom surface of the gate structure may be suppressed. Accordingly, an operation failure caused by a disturbance operation of a transistor may be reduced.

### BRIEF DESCRIPTION OF THE DRAWINGS

FIGS. 1 and 2 are a plan view and a sectional view showing a DRAM device according to exemplary embodiments.

FIGS. 3 and 4 are a plan view and a perspective view showing a first active pattern and a first gate structure of the DRAM device in a memory cell region.

FIGS. 5 to 7 are sectional views showing an active pattern and device isolation patterns of the DRAM device in the memory cell region, a core-peripheral region, and a boundary region according to the exemplary embodiments.

FIGS. 8 to 21 are sectional views and plan views showing a method for forming active patterns of a semiconductor device according to an exemplary embodiment.

FIG. 22 is a sectional view showing an active pattern and device isolation patterns of a DRAM device in a memory cell region, a core-peripheral region, and a boundary region according to exemplary embodiments.

FIGS. 23 to 26 are sectional views showing a method for manufacturing a DRAM device according to exemplary embodiments.

### DETAILED DESCRIPTION OF THE EMBODIMENTS

Hereinafter, exemplary embodiments of the present disclosure will be described in detail with reference to the accompanying drawings.

Hereinafter, two directions that are parallel to a top surface of a substrate and perpendicular to each other will be defined as first and second directions, respectively. In addition, a direction that is parallel to the top surface of the substrate and oblique to the first direction (i.e., a diagonal direction) will be defined as a third direction, and a direction that is parallel to the top surface of the substrate and perpendicular to the third direction will be defined as a fourth direction.

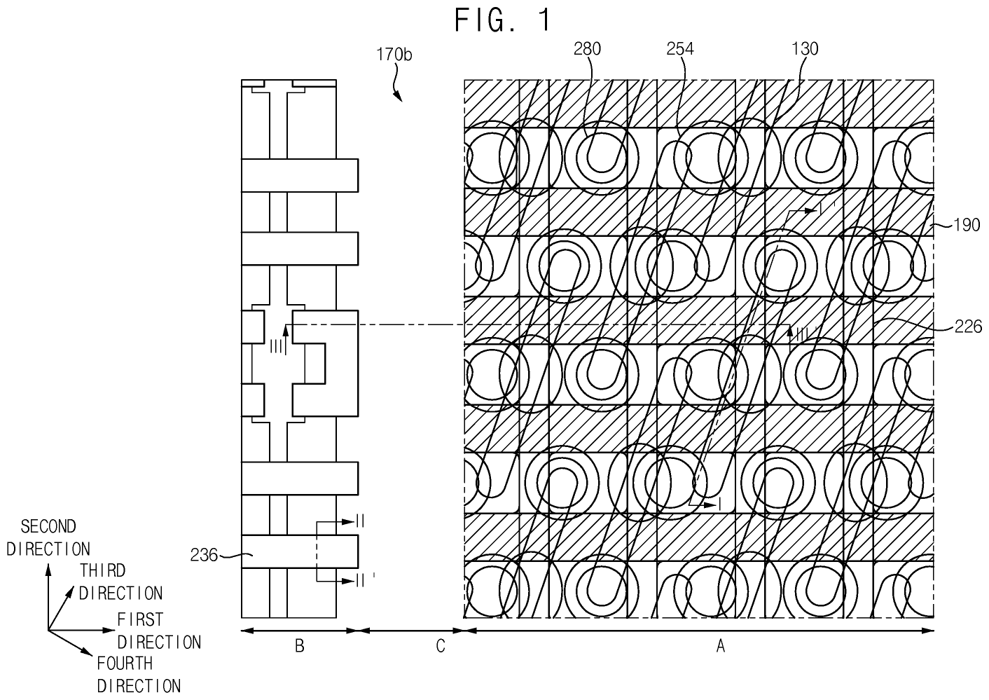

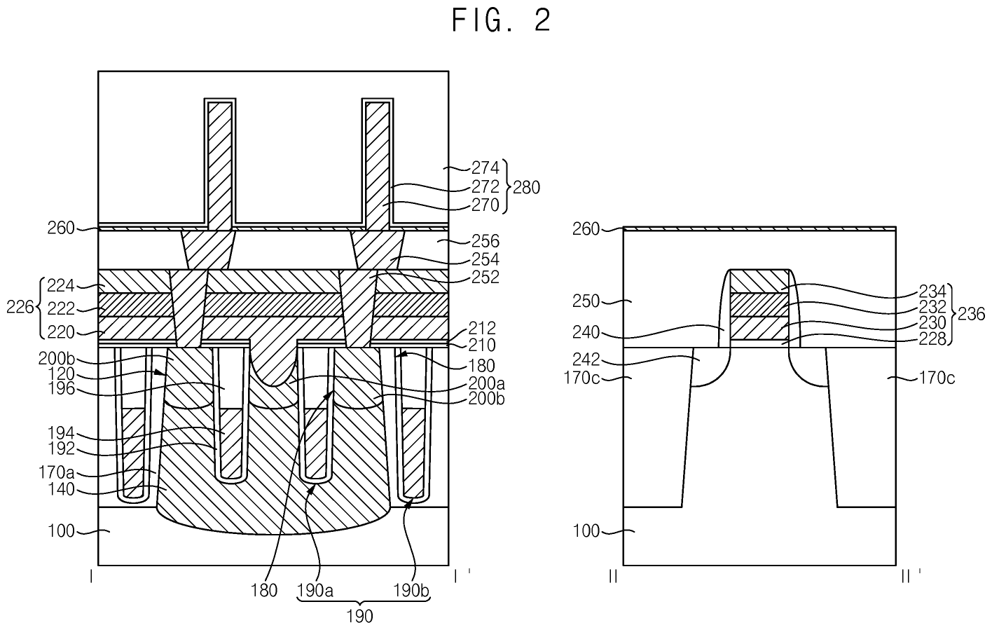

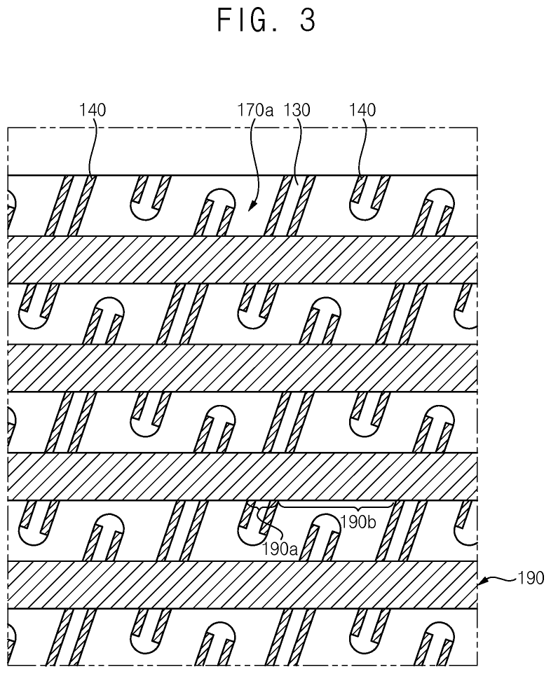

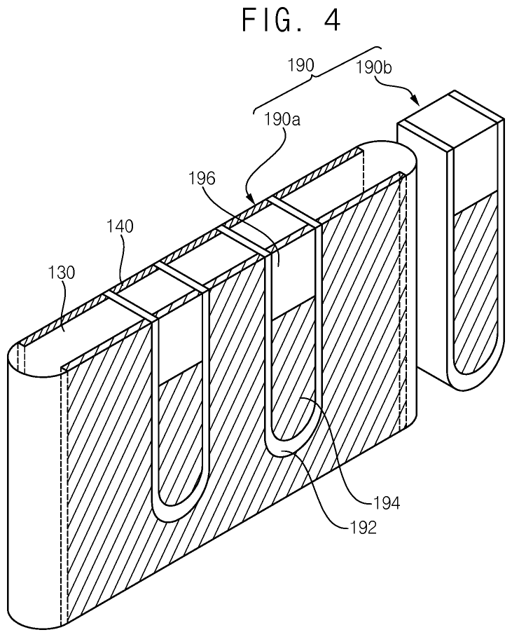

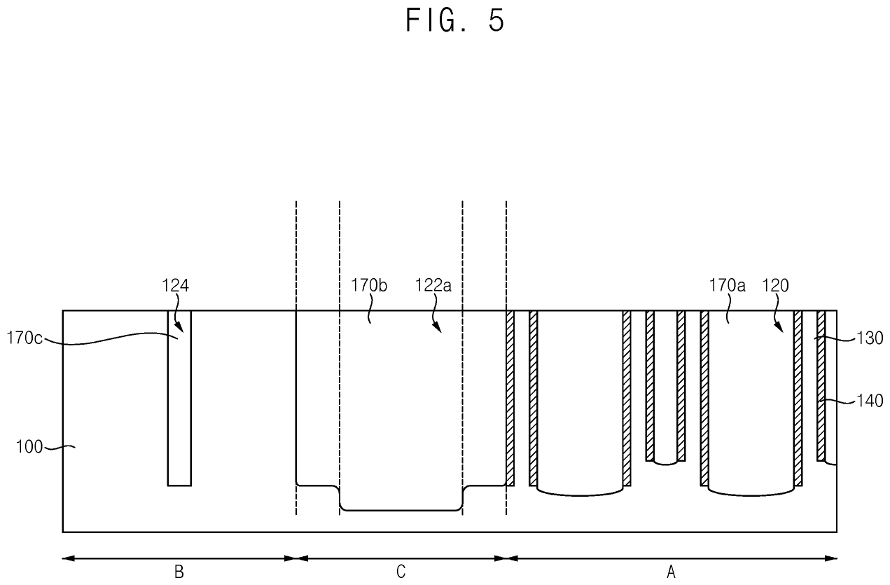

FIGS. 1 and 2 are a plan view and a sectional view showing a DRAM device according to exemplary embodiments. FIGS. 3 and 4 are a plan view and a perspective view showing a first active pattern and a first gate structure of the DRAM device in a memory cell region. FIGS. 5 to 7 are sectional views showing an active pattern and device isolation patterns of the DRAM device in the memory cell region, a core-peripheral region, and a boundary region according to the exemplary embodiments.

FIG. 2 is a sectional view taken along lines I-I′ and II-II′ of FIG. 1. In FIG. 2, a sectional view taken along the line I-I′ corresponds to a view taken along a barrier impurity region.

Referring to FIGS. 1 to 4, a substrate 100 may be provided. The substrate 100 may include a memory cell region A, a core-peripheral region B, and a boundary region C located between the memory cell region A and the core-peripheral region B.

The substrate 100 may include a single crystal semiconductor material. The substrate 100 may include a semiconductor material such as silicon, germanium, and silicon-germanium. According to an exemplary embodiment, the substrate 100 may be formed of single crystal silicon.

The core-peripheral region B may be spaced apart from an edge of the memory cell region A to surround the memory cell region A. The boundary region C may be a region for separating the memory cell region A from the core-peripheral region B.

Trenches may be provided in the substrate 100, and an insulating material may be embedded inside the trenches to form a device isolation pattern. A region in which the device isolation pattern is formed may be provided as a device separation region. A region of the substrate 100 protruding between the trenches may be defined as an active pattern. A top surface of the active pattern may be provided as an active region.

A first trench 120 may be provided in the substrate 100 in the memory cell region A. First active patterns 130 may be formed between first trenches 120 in the memory cell region A. A first device isolation pattern 170a may be provided in the first trench 120. The first device isolation pattern 170a may cover a side wall of the first active pattern 130.

Each of the first active patterns 130 may have an isolated shape extending in the third direction. For example, the third direction may be a longitudinal direction, that is, a major axis direction of the first active pattern 130 in the memory cell region A. The fourth direction may be a minor axis direction of the first active pattern 130. The first active pattern 130 may include first and second side wall surfaces of a major axis, and third and fourth side wall surfaces of a minor axis. The first active patterns 130 may be regularly arranged while being spaced apart from each other in the first and second directions.

A second trench 122a may be provided over the whole substrate 100 in the boundary region C, and a second device isolation pattern 170b may be provided inside the second trench 122a. The boundary region C may have a width that is sufficient to separate the memory cell region A from the core-peripheral region B. Therefore, a width of the second trench 122a may be wider than a width of the first trench 120.

A bottom surface of the second trench 122a may have a step without being flat. The second trench 122a may include: a first region that is adjacent to the memory cell region Ain the boundary region C; a second region that is adjacent to the core-peripheral region B in the boundary region C; and a third region between the first region and the second region. According to the exemplary embodiment, in the boundary region C, a bottom surface of the first region may have a first step, a bottom surface of the second region may have a second step, and a bottom surface of the third region may have a third step that is lower than each of the first and second steps. The step may indicate a height of the bottom surface.

As one example, as shown in FIG. 5, the first step and the second step may be substantially the same, and the third step may be lower than each of the first and second steps.

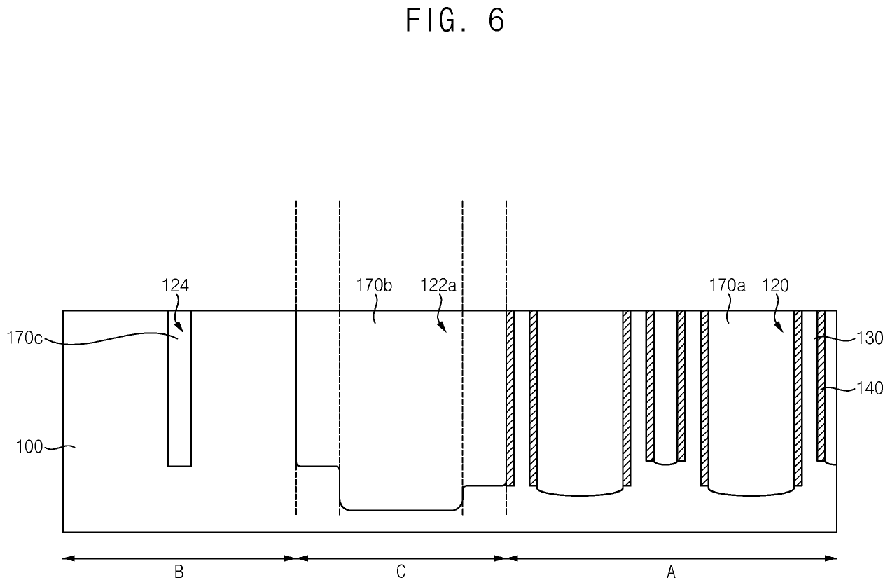

As another example, as shown in FIG. 6, the second step may be higher than the first step, and the third step may be lower than each of the first and second steps.

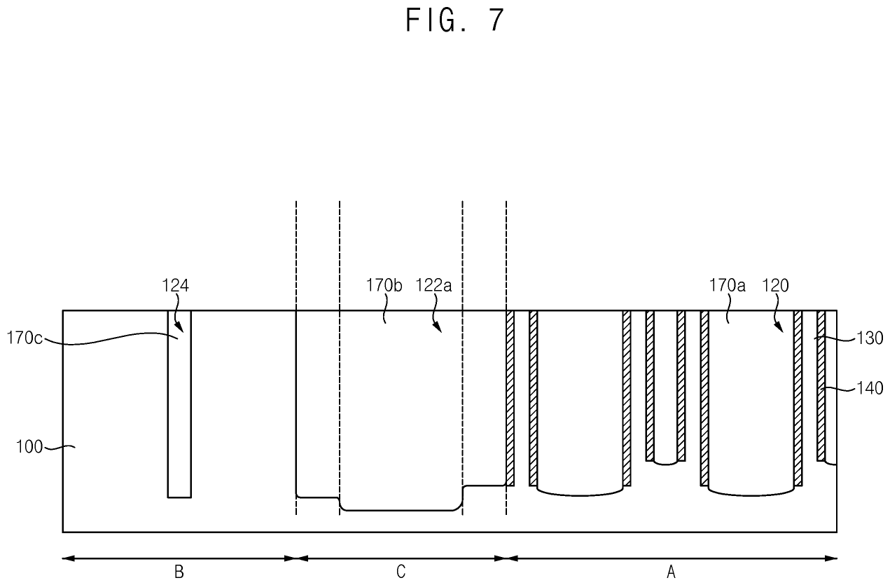

As still another example, as shown in FIG. 7, the second step may be lower than the first step, and the third step may be lower than each of the first and second steps.

A third trench 124 may be provided in the substrate 100 in the core-peripheral region B, and a third device isolation pattern 170c may be provided inside the third trench 124. A region of the substrate 100 on which the third device isolation pattern 170c is not formed may be a third active pattern. Atop surface of the third active pattern may be provided as an active region.

Each of the first device isolation pattern 170a, the second device isolation pattern 170b, and the third device isolation pattern 170c may include an insulating material. According to the exemplary embodiment, each of the first to third device isolation patterns 170a, 170b, and 170c may include silicon oxide and/or silicon nitride.

A barrier impurity region 140 may be selectively provided only on the first and second side wall surfaces of the major axis of each of the first active patterns 130 in the memory cell region A. The barrier impurity region 140 may include a first impurity having a negative charge when doped to the substrate 100. For example, when doped, the barrier impurity region 140 may have a negative charge relative to the substrate 100. The first impurity may include germanium or fluorine.

Since the barrier impurity region 140 is formed on the first and second side wall surfaces of the major axis of the first active pattern 130 facing each other in the fourth direction, barrier impurity regions 140 may face each other in the fourth direction. Therefore, the barrier impurity region 140 may be formed at an edge of the first active pattern 130 in the fourth direction, and may not be formed at a central portion of the first active pattern 130 in the fourth direction.

In addition, the barrier impurity region 140 may not be formed on the third and fourth side wall surfaces of the minor axis of the first active pattern 130. For example, the barrier impurity region 140 may not be formed on a side wall of an end of the first active pattern 130 in the third direction.

Meanwhile, the barrier impurity region 140 may not be formed in the third active pattern in the core-peripheral region B. A recessed channel transistor may not be provided on the core-peripheral region B, and only a planar transistor may be provided on the core-peripheral region B. For example, a gate structure buried in the substrate may not be provided in the core-peripheral region B. Therefore, the barrier impurity region 140 may not be required.

In the memory cell region A, the DRAM device may include a recessed channel transistor, a bit line structure 226, a contact plug 252, a landing pad 254, and a capacitor 280. A unit memory cell of the DRAM device may include the recessed channel transistor and the capacitor 280.

A gate trench 180 extending in the first direction may be provided on upper portions of the first active pattern 130 and the first device isolation pattern 170a in the memory cell region A. A first gate structure 190 may be provided inside the gate trench 180. The first gate structure 190 may extend in the first direction. The first gate structure 190 may include a first portion formed inside the first active pattern 130, and a second portion formed inside the first device isolation pattern 170a.

Two first gate structures 190 may be spaced apart from each other in one unit first active pattern 130. Two recessed channel transistors may be formed in one unit first active pattern 130. One first gate structure 190 may be disposed in each of first device isolation patterns 170a making contact with both ends (i.e., both ends in the major axis direction) of the one unit first active pattern 130.

The first portion of the first gate structure 190 disposed inside the first active pattern 130 may be provided as a main gate structure 190a of a recess transistor. The second portion of the first gate structure 190 disposed inside the first device isolation pattern 170a may be provided as a pass gate structure 190b that does not actually operate as a transistor.

The first gate structure 190 may include a gate insulating layer 192, a gate electrode 194, and a capping pattern 196.

First and second impurity regions 200a and 200b provided as source/drain regions may be provided on an upper portion of the first active pattern 130 that is adjacent to both sides of the first gate structure 190. The first and second impurity regions 200a and 200b may be provided on the upper portion of the first active pattern 130 between the first gate structures 190. The first gate structure 190 and the first and second impurity regions 200a and 200b may be provided as a recessed channel transistor, which is a selection transistor of a memory cell.

The first impurity region 200a may be located at a central portion of the first active pattern 130 in the major axis direction, and the second impurity region 200b may be located at both edges of the first active pattern 130 in the major axis direction.

A first insulating pattern 210 and a second insulating pattern 212 may be stacked on the substrate 100, the first device isolation pattern 170a, and the first gate structure 190 in the memory cell region A. For example, the first insulating pattern 210 may include oxide such as silicon oxide, and the second insulating pattern 212 may include nitride such as silicon nitride.

In the memory cell region A, a recess may be included in a partial region of the substrate 100 on which the first insulating pattern 210 and the second insulating pattern 212 are not formed. A top surface of the first impurity region 200a may be exposed through a bottom surface of the recess.

The barrier impurity region 140 may be provided as a barrier for preventing charges that have moved to the first active pattern 130 from leaking to a lower portion of the main gate structure 190a. Therefore, a bottom surface of the barrier impurity region 140 may be lower than a bottom surface of the first gate structure 190. For example, the barrier impurity region 140 may extend from a top surface of the first active pattern 130 to a lower portion of a bottom surface of the first device isolation pattern 170a. The barrier impurity region 140 may partially overlap the first and second impurity regions 200a and 200b.

In the memory cell region A, the bit line structure 226 may be provided on the second insulating pattern 212 and the recess. The bit line structure 226 may be electrically connected to the first impurity region 200a.

The bit line structure 226 may include a first conductive pattern 220, a first barrier metal pattern (not shown), a first metal pattern 222, and a first hard mask pattern 224.

The first conductive pattern 220 may include, for example, polysilicon doped with impurities. The first barrier metal pattern may include, for example, tungsten nitride, titanium nitride, titanium, tantalum nitride, tantalum, or TiSiN. The first metal pattern 222 may include, for example, tungsten. The first hard mask pattern 224 may include, for example, silicon nitride.

The bit line structure 226 may extend in the second direction, and a plurality of bit line structures 226 may be formed in the first direction. According to the exemplary embodiments, a spacer (not shown) may be provided on a side wall of the bit line structure 226. Although not shown, the spacer may have a structure in which a plurality of spacers are laterally stacked.

A planar-type second gate structure 236 may be provided on the substrate 100 in the core-peripheral region B. The second gate structure 236 may have a structure in which a gate insulating layer pattern 228, a second conductive pattern 230, a second barrier metal pattern (not shown), a second metal pattern 232, and a second hard mask pattern 234 are stacked. A spacer 240 may be provided on a side wall of the second gate structure 236.

According to the exemplary embodiment, a structure of the bit line structure 226 in which the first conductive pattern 220, the first barrier metal pattern, the first metal pattern 222, and the first hard mask pattern 224 are stacked may be the same as a structure of the second gate structure 236 in which the second conductive pattern 230, the second barrier metal pattern, the second metal pattern 232, and the second hard mask pattern 234 are stacked.

A first interlayer insulating layer (not shown) filling a gap between the bit line structures 226 and covering the bit line structures 226 and the second gate structure 236 may be provided.

The contact plug 252 and the landing pad 254 passing through the first interlayer insulating layer, the second insulating pattern 212, and the first insulating pattern 210 to make contact with the second impurity region 200b may be provided on the memory cell region A. The contact plug 252 may be disposed between the bit line structures 226. The landing pad 254 may be formed on the contact plug 252. An insulating pattern 256 may be provided between landing pads 254.

An etching stop layer 260 may be provided on the landing pad 254, the insulating pattern 256, and the first interlayer insulating layer. The capacitor 280 passing through the etching stop layer 260 to make contact with the landing pad 254 may be provided.

The etching stop layer 260 may include, for example, silicon nitride, silicon oxynitride, and the like.

The capacitor 280 may include a lower electrode 270, a dielectric layer 272, and an upper electrode 274. A bottom surface of the lower electrode 270 may make contact with the landing pad 254. Therefore, the capacitor 280 may be electrically connected to the second impurity region 200b.

According to the exemplary embodiment, the lower electrode 270 may include titanium nitride (TiN) or titanium (Ti). According to the exemplary embodiment, the dielectric layer 272 may include metal oxide having a high dielectric constant. For example, the dielectric layer 272 may include or may be formed of HfO₂, ZrO₂, TiO₂, TaO, or La₂O₃. The upper electrode 274 may include, for example, at least one selected from titanium nitride (TiN), titanium (Ti), tantalum (Ta), tantalum nitride (TaN), ruthenium (Ru), tungsten, tungsten nitride, Nb, NbN, indium tin oxide (ITO), Ta-doped SnO₂, Nb-doped SnO₂, Sb-doped SnO₂, and V-doped SnO₂.

Hereinafter, an operation of the memory cell of the DRAM device, which has the structure described above, will be described.

First, the main gate structure 190a of the recessed channel transistor corresponding to the selected memory cell may be turned on, and charges may be charged in the capacitor 280 electrically connected to the recessed channel transistor. Thereafter, the main gate structure 190a may be turned off, and data may be written by the charges charged in the capacitor 280.

Meanwhile, the pass gate structure 190b may be provided inside the first device isolation pattern 170a that is adjacent to the first active pattern 130 of the selected memory cell. As the DRAM device is integrated, the pass gate structure 190b may be adjacent to the second impurity region 200b of the first active pattern 130, so that the pass gate structure 190b may perform a disturbance operation in which the pass gate structure 190b is turned on and off similarly to an actual transistor.

As described above, when a disturbance transistor by the pass gate structure 190b is turned on, the charges stored in the capacitor 280 may move to the second impurity region 200b and the first active pattern 130 disposed under the second impurity region 200b through the landing pad 254 and the contact plug 252. In addition, when the disturbance transistor by the pass gate structure 190b is turned off, the charges that have moved to the first active pattern 130 may move back to the capacitor 280 so as to be charged in the capacitor 280.

However, after the charges move to the first active pattern 130 between the main gate structure 190a and the first device isolation pattern 170a, the charges may leak from a lower portion of the first active pattern 130 to a lower portion of a bottom surface of the main gate structure 190a. In this case, since the charges may not move back to the capacitor 280, a number of charges stored in the capacitor 280 may be reduced, and data stored in the capacitor 280 may be changed.

In a case of the memory cell described above, the barrier impurity region 140 may be provided on the first and second side wall surfaces of the major axis of the first active pattern 130. The barrier impurity region 140 may have a negative charge. In addition, the barrier impurity region 140 may not be provided on the third and fourth side wall surfaces of the first active pattern 130.

Therefore, an electric field may be applied to the charges that have moved from the capacitor 280 to the first active pattern 130 so that the charges may repel each other from the first and second side wall surfaces of the major axis of the first active pattern 130, and leakage of the charges to the lower portion of the main gate structure 190a through the first and second side wall surfaces of the first active pattern 130 may be suppressed. In addition, since the barrier impurity region 140 is not provided on the third and fourth side wall surfaces of the minor axis of the first active pattern 130, an electric field may not be applied to the charges that have moved from the capacitor 280 to the first active pattern 130 to allow the charges to move to the central portion of the first active pattern 130.

Therefore, even when the charges move from the capacitor 280 to the first active pattern 130, the charges may move back to the capacitor 280 without leaking to the lower portion of the bottom surface of the main gate structure 190a. Thus, the data stored in the capacitor 280 may be maintained.

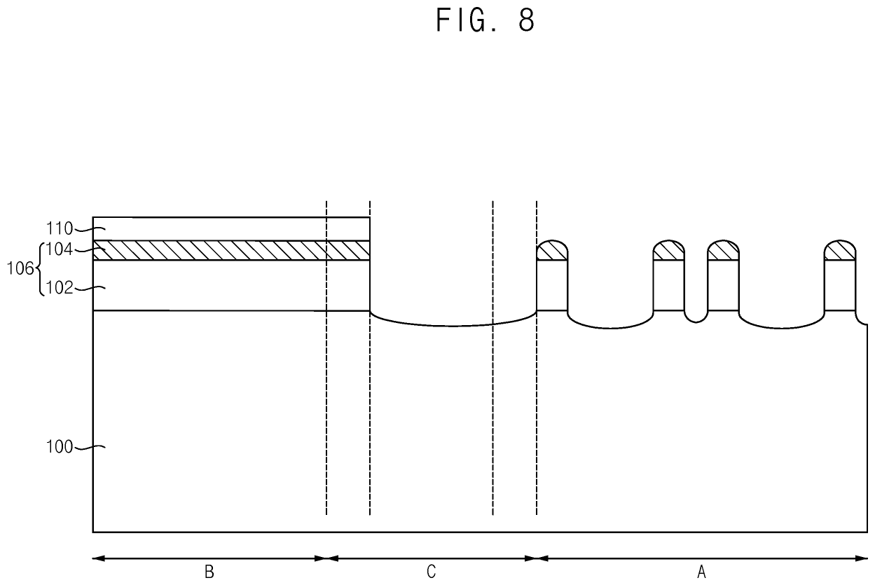

FIGS. 8 to 21 are sectional views and plan views showing a method for forming active patterns of a semiconductor device according to an exemplary embodiment.

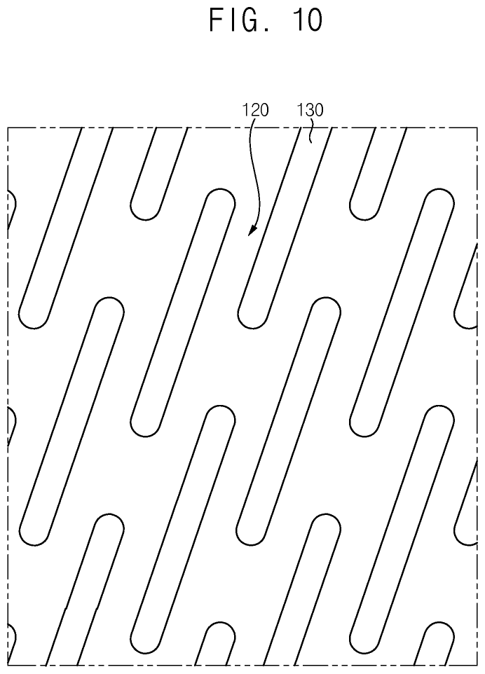

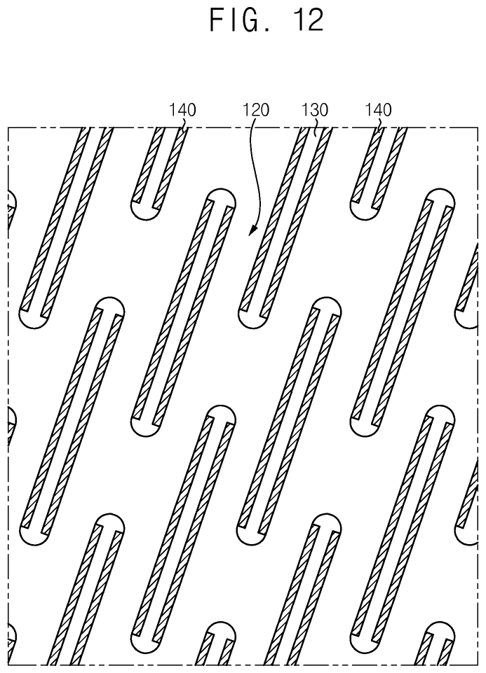

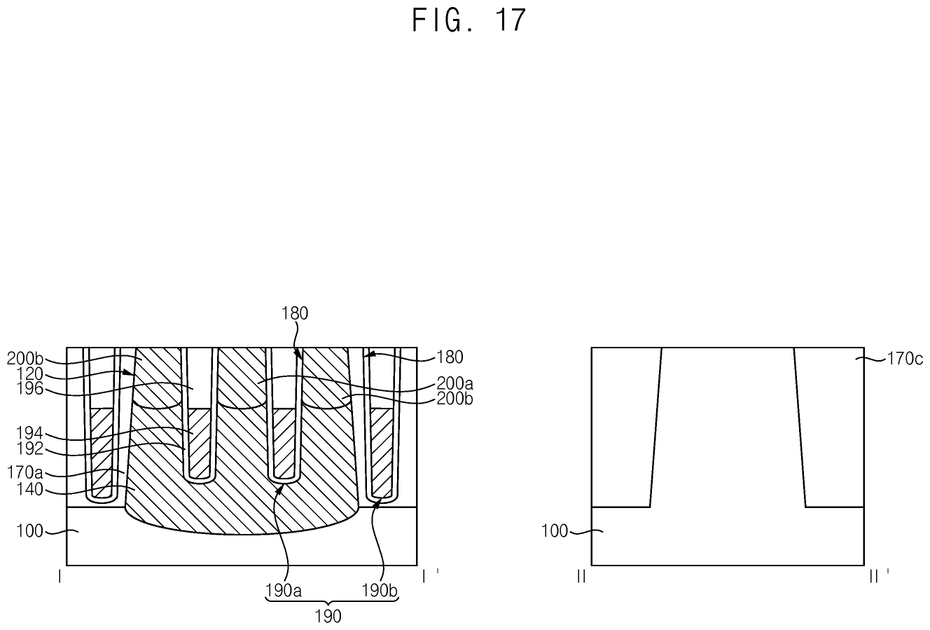

FIGS. 8, 9, 11, and 13 to 16 are sectional views taken along a line III-III′ of FIG. 1. FIGS. 10 and 12 are plan views showing a memory cell region. FIGS. 17 to 21 are sectional views taken along a line I-I′ and a line II-II′ of FIG. 1.

Referring to FIG. 8, a substrate 100 including a memory cell region A, a core-peripheral region B, and a boundary region C between the memory cell region A and the core-peripheral region B may be provided. A mask pattern structure 106 for forming a trench may be formed on the substrate 100.

The mask pattern structure 106 formed on the substrate 100 in the memory cell region A may cover a region in which a first active pattern is to be formed. For example, a region between mask pattern structures 106 may be a region in which a first device isolation pattern 170a is to be formed. The mask pattern structure 106 may completely cover the substrate 100 in the core-peripheral region B. In addition, the mask pattern structure 106 may partially cover the substrate 100 in the boundary region C that is adjacent to the core-peripheral region B and expose all of the substrate 100 in the remaining boundary region C.

According to an exemplary embodiment, the mask pattern structure 106 may have a structure in which at least two mask patterns are stacked. At least one pattern included in the mask pattern structure 106 may include a material having a selectivity with respect to the substrate 100. According to the exemplary embodiment, the mask pattern structure 106 may have a structure in which a silicon oxide layer pattern 102 and a polysilicon pattern 104 are stacked.

According to the exemplary embodiment, the mask pattern structure 106 may be formed through a quadruple patterning technique (QPT) process or a double patterning technique (DPT) process.

A first photoresist layer may be formed to cover the mask pattern structure 106. The first photoresist layer may be patterned through a photolithography process to form a first photoresist pattern 110 covering the mask pattern structure 106 on the core-peripheral region B. In this case, the first photoresist pattern 110 may also be formed on the mask pattern structure 106 partially formed on the boundary region C. In addition, the first photoresist pattern 110 may not be formed on the substrate 100 in the boundary region C, the substrate 100 in the memory cell region A, and the mask pattern structure 106.

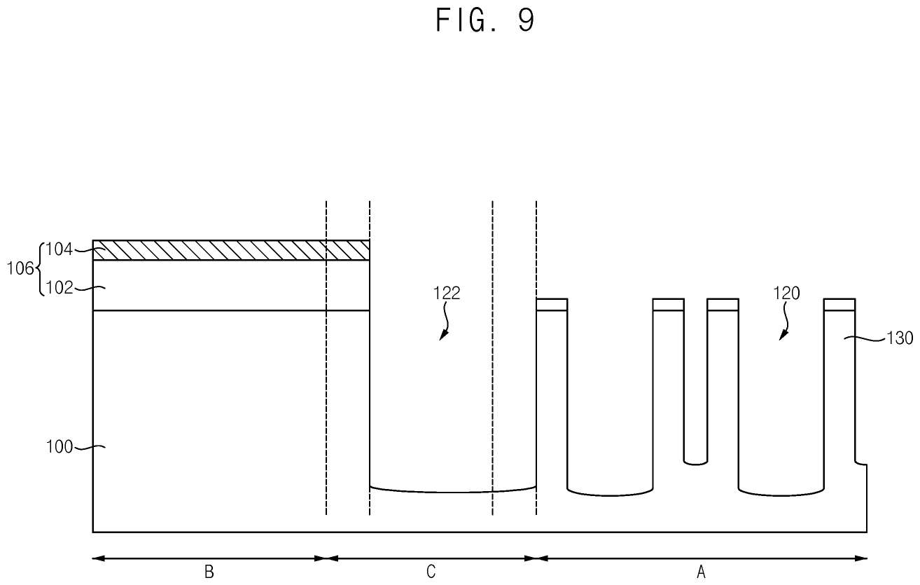

Referring to FIGS. 9 and 10, trenches may be formed by etching an upper portion of the substrate 100 by using the mask pattern structure 106 and the first photoresist pattern 110 as an etching mask.

Through the above process, a first trench 120 and a first active pattern 130 may be formed in the memory cell region A. A preliminary second trench 122 may be formed in the boundary region C. In this case, since the substrate 100 in the core-peripheral region B is covered by the mask pattern structure 106 and the first photoresist pattern 110, a trench may not be formed in the core-peripheral region B.

Each of the first active patterns 130 may have an isolated shape in which the third direction is a longitudinal direction.

After the etching process is performed, the mask pattern structure 106 on the boundary region C and the memory cell region A may be etched so that a portion of the of the mask pattern structure 106 may be removed (e.g., a thickness of the mask pattern structure 106 is reduced). However, in contrast to the boundary region C and the memory cell region A, etching the mask pattern structure 106 on the substrate 100 in the core-peripheral region B may remove less of the mask pattern structure 106. For example, subsequent to etching, the thickness of the mask pattern structure 106 may be greater in the core-peripheral region B than in the boundary region C and the memory cell region A. However, the first photoresist pattern 110 may be removed by the etching process in the core-peripheral region B, the boundary region C, and memory cell region A.

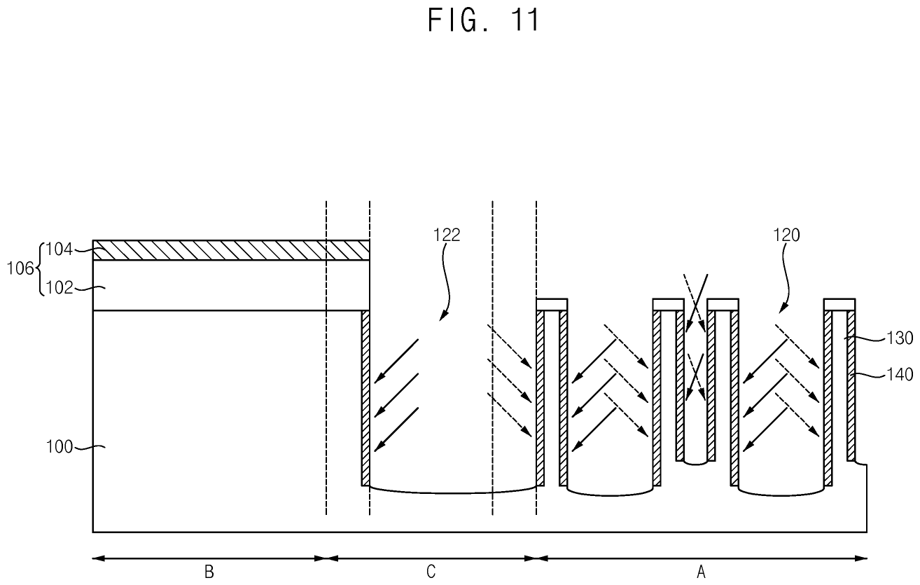

Referring to FIGS. 11 and 12, first and second side wall surfaces of a major axis of each of the first active patterns 130 in the memory cell region A may be selectively doped with a first impurity so as to form a barrier impurity region 140. Due to the doping of the impurity, the barrier impurity region 140 may have a negative charge.

According to the exemplary embodiment, a process of performing doping with the first impurity may be performed through an inclined ion implantation process. According to the ion implantation process, ion implantation may be performed with a first inclination to dope the first side wall surface of each of the first active patterns 130 with the first impurity, and ion implantation may be performed with a second inclination to dope the second side wall surface of each of the first active patterns 130 with the first impurity. Therefore, the first and second side wall surfaces of each of the first active patterns 130 facing each other in the fourth direction may be doped with the first impurity.

The first impurity doped to the barrier impurity region 140 may include germanium or fluorine. The barrier impurity region 140 may apply an electric field so that electrons that have moved from the capacitor 280 may not move to a lower portion of a first gate structure 190 so as to be dissipated.

Since the barrier impurity region 140 is formed on each of the first and second side wall surfaces of the major axis within each of the first active patterns 130, barrier impurity regions 140 may face each other in the fourth direction. For example, the barrier impurity region 140 may be formed on surfaces of both ends of the first active patterns 130 in the fourth direction.

When viewed in a plan view, only an edge region of the first active pattern 130 in the fourth direction may be doped with the first impurity, and a central portion of the first active pattern 130 in the fourth direction may not be doped with the first impurity.

In addition, the barrier impurity region 140 may not be formed on third and fourth side wall surfaces of a minor axis of the first active pattern 130. For example, the barrier impurity region 140 may not be formed on side walls of both ends of the first active pattern 130 in the third direction.

When the third and fourth side wall surfaces of the first active pattern 130 in a minor axis direction are doped with the first impurity, the first impurity may apply the electric field toward the central portion of the first active pattern 130, so that the electrons that have moved from the capacitor 280 may move to the lower portion of a first gate structure 190 so as to be dissipated. Therefore, preferably, the barrier impurity region 140 may not be formed on the third and fourth side wall surfaces of the minor axis of the first active pattern 130.

Meanwhile, since the substrate 100 in the core-peripheral region B is covered by the mask pattern structure 106, the first impurity may not be doped.

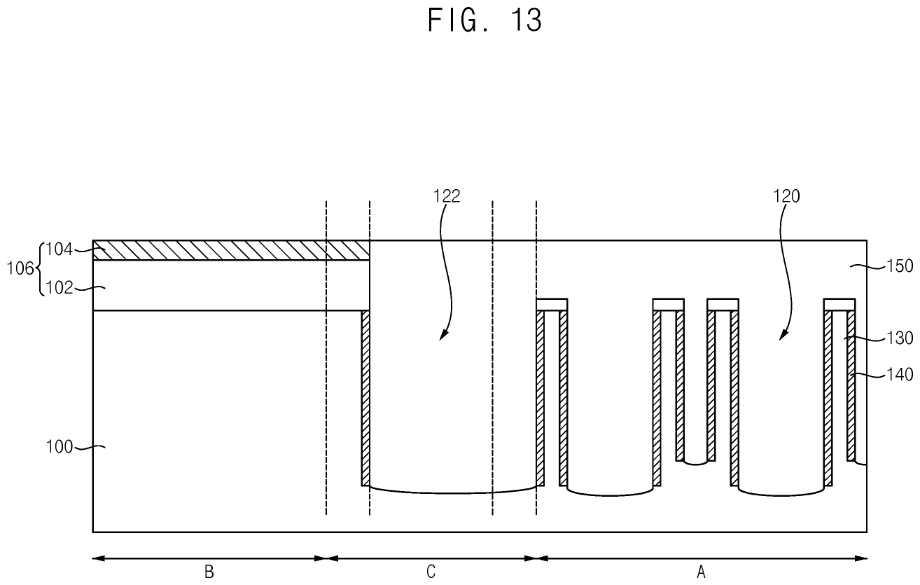

Referring to FIG. 13, a preliminary sacrificial layer may be formed to completely fill the first trench 120 and the preliminary second trench 122. In this case, the preliminary sacrificial layer may cover the mask pattern structure 106. Thereafter, a sacrificial layer 150 may be formed by planarizing the preliminary sacrificial layer so that a top surface of the mask pattern structure 106 may be exposed. The planarization process may include an etch-back process and/or a chemical mechanical polishing process.

The sacrificial layer 150 may be formed by using a material that has excellent gap filling characteristics and is easily removed through an etching process. According to the exemplary embodiment, the sacrificial layer 150 may be formed by using a spin-on hard mask material, silicon nitride, or silicon oxide.

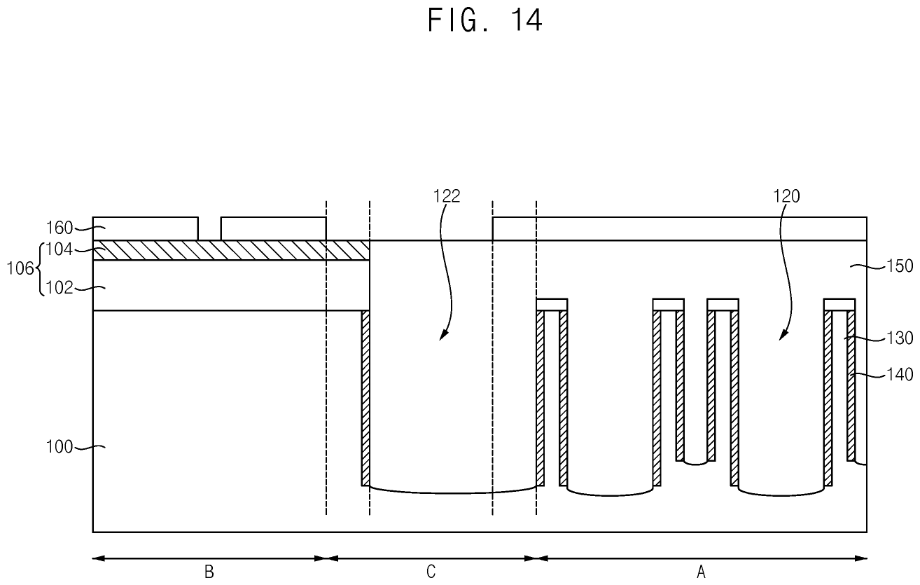

Referring to FIG. 14, a second photoresist layer may be formed to cover the mask pattern structure 106 and the sacrificial layer 150. The second photoresist layer may be patterned through a photolithography process to form a second photoresist pattern 160.

The second photoresist pattern 160 may cover the sacrificial layer 150 on the memory cell region A and a portion of the boundary region C that is adjacent to the memory cell region A. The sacrificial layer 150 on the remaining portion of the boundary region C and the mask pattern structure 106 may be exposed by the second photoresist pattern 160.

In addition, the second photoresist pattern 160 may selectively expose a region of the substrate 100 in the core-peripheral region B where a third device isolation pattern 170c is to be formed. For example, the second photoresist pattern 160 may completely cover a region of the core-peripheral region B corresponding to the active region.

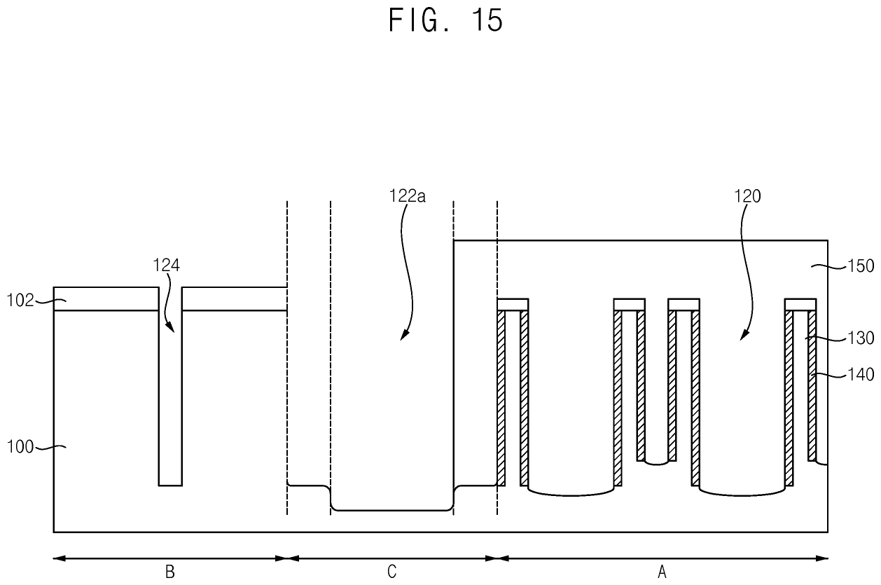

Referring to FIG. 15, the mask pattern structure 106 and the sacrificial layer 150 may be anisotropically etched by using the second photoresist pattern 160 as an etching mask.

Subsequently, the substrate 100 disposed under the mask pattern structure 106 in the core-peripheral region B may be etched to form a third trench 124. A region of the substrate 100 in the core-peripheral region B in which the third trench 124 is not formed may be provided as an active region.

In addition, according to the etching process, the sacrificial layer 150 in the boundary region C and the substrate 100 under the mask pattern structure 106 may be additionally etched to form a second trench 122a in the boundary region C. According to the etching process, a portion of a side wall of the preliminary second trench 122 in the boundary region C, which is doped with the first impurity, may be removed.

When the etching process is performed, most of the second photoresist pattern 160 and the mask pattern structure 106 may be removed.

The second trench 122a may include a portion pre-etched in an etching process for forming the first trench 120, and a portion additionally etched in an etching process for forming the third trench 124. An etching rate of a region of the sacrificial layer 150 may be faster than an etching rate of a region of the substrate 100 in the boundary region C in the etching process for forming the third trench 124. Therefore, a region of the second trench 122a in which the substrate 100 is additionally etched under the region of the sacrificial layer 150 may have a lowest bottom surface.

As described above, a bottom surface of the second trench 122a may have a step without being flat. According to the exemplary embodiment, a bottom surface of a first region that is adjacent to the memory cell region A in the boundary region C may have a first step, a bottom surface of a second region that is adjacent to the core-peripheral region B may have a second step, and a bottom surface of a third region between the first region and the second region may have a third step that is lower than each of the first and second steps. The step may indicate a height of a top surface of the bottom surface.

According to the etching process, a shape of the step of the bottom surface of the second trench 122a may vary according to a thickness by which the substrate 100 is etched.

As one example, the substrate 100 under the mask pattern structure 106 in the boundary region C may be etched to a same depth as the bottom surface of the first trench 120 that is adjacent to the boundary region C. In this case, as shown in FIG. 15, the first step and the second step may be substantially the same, and the third step may be lower than each of the first and second steps.

As another example, the substrate 100 under the mask pattern structure 106 in the boundary region C may be etched to a position higher than the bottom surface of the first trench 120 that is adjacent to the boundary region C. In this case, as shown in FIG. 6, the second step may be higher than the first step, and the third step may be lower than each of the first and second steps.

As still another example, the substrate 100 under the mask pattern structure 106 in the boundary region C may be etched to a position lower than the bottom surface of the first trench 120 that is adjacent to the boundary region C. In this case, as shown in FIG. 7, the second step may be lower than the first step, and the third step may be lower than each of the first and second steps.

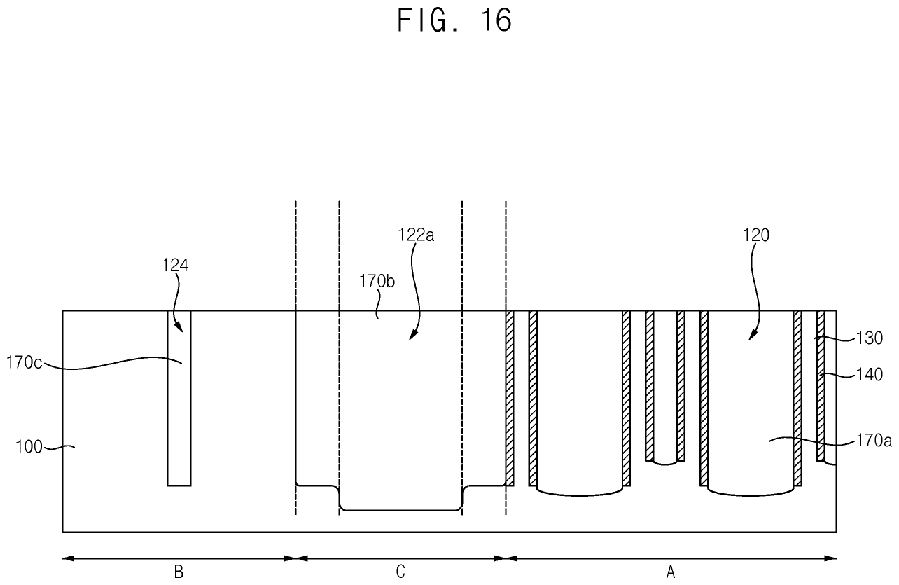

Referring to FIG. 16, the sacrificial layer 150 may be removed. In addition, the remaining mask pattern structure 106 may be removed.

An insulating film may be formed inside the first to third trenches 120, 122a, and 124, so that first to third device isolation patterns 170a, 170b, and 170c may be formed inside the first to third trenches 120, 122a, and 124, respectively.

Hereinafter, descriptions will be given with reference to sectional views taken along lines I-I′ and II-II′ of FIG. 1.

Referring to FIG. 17, upper portions of the first active pattern 130 and the first device isolation pattern 170a in the memory cell region A may be etched to form a gate trench 180 extending in the first direction. A first gate structure 190 may be formed inside the gate trench 180.

An upper portion of the first active pattern 130 on both sides of the first gate structure 190 may be doped with an N-type impurity to form first and second impurity regions 200a and 200b. The first and second impurity regions 200a and 200b may be provided as a source and a drain of a recessed channel transistor. The first impurity region 200a may be located at a central portion of the first active pattern 130 in a major axis direction, and the second impurity region 200b may be located at both edges of the first active pattern 130 in the major axis direction.

The first gate structure 190 may include a gate insulating layer 192, a gate electrode 194, and a capping pattern 196. The first gate structure 190 disposed inside the first active pattern 130 may be provided as a main gate structure 190a of the recessed channel transistor included in a memory cell. The first gate structure 190 disposed inside the first device isolation pattern 170a may be provided as a pass gate structure 190b that does not actually operate as a transistor.

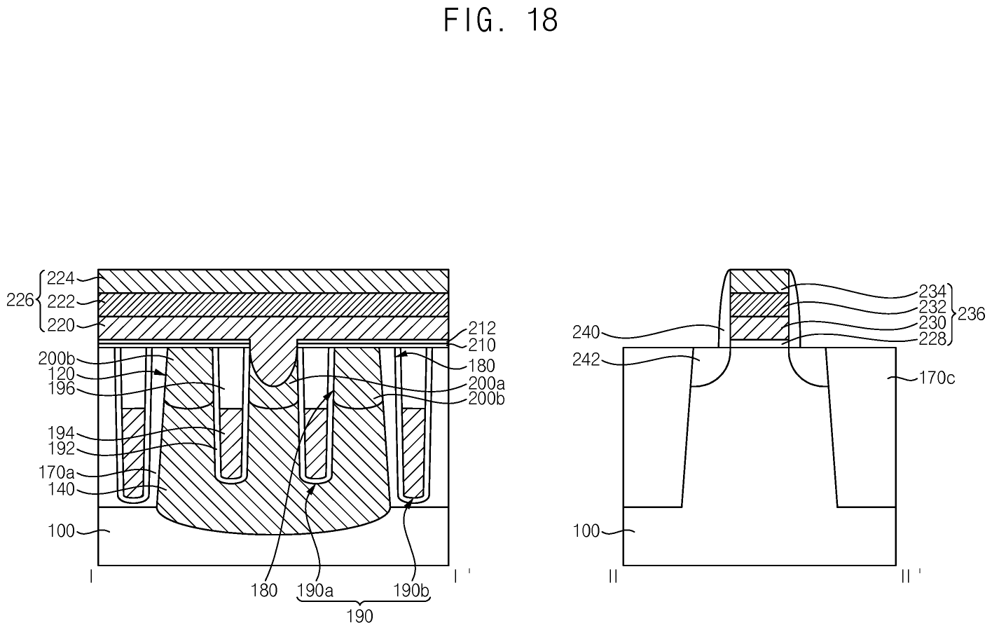

Referring to FIG. 18, a first insulating pattern 210 and a second insulating pattern 212 may be formed on the substrate 100, the first to third device isolation patterns 170a, 170b, and 170c, and the first gate structure 190. A recess (not shown) may be formed in some substrates 100 on which the first insulating pattern 210 and the second insulating pattern 212 are not formed. A top surface of the first impurity region 200a may be exposed through a bottom surface of the recess.

A bit line structure 226 extending in the second direction may be formed on the second insulating pattern 212 and the recess in the memory cell region A. The bit line structure 226 may be electrically connected to the first impurity region 200a. In addition, a planar-type second gate structure 236 may be formed on the substrate 100 in the core-peripheral region B.

The bit line structure 226 may have a structure in which a first conductive pattern 220, a barrier metal pattern (not shown), a first metal pattern 222, and a first hard mask pattern 224 are stacked. The second gate structure 236 may have a structure in which a gate insulating layer pattern 228, a second conductive pattern 230, a second barrier metal pattern (not shown), a second metal pattern 232, and a second hard mask pattern 234 are stacked.

According to the exemplary embodiment, a spacer 240 may be formed on a side wall of the bit line structure 226 and a side wall of the second gate structure 236.

An impurity region 242 may be formed in the substrate 100 in the core-peripheral region B that is adjacent to both sides of the second gate structure 236.

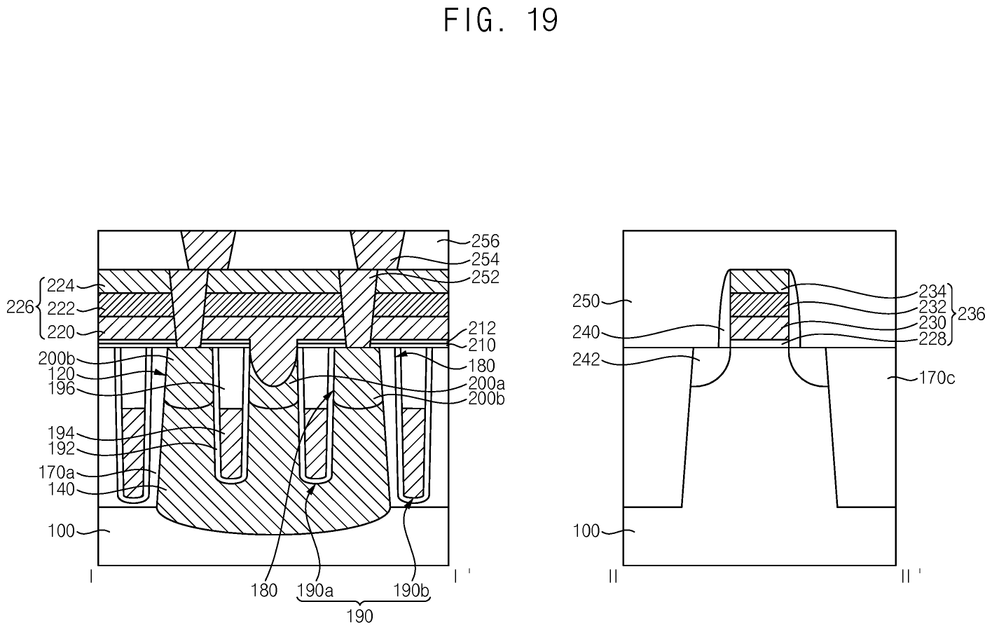

Referring to FIG. 19, a first interlayer insulating layer 250 covering bit line structures 226 and the second gate structure 236 may be formed.

A contact hole exposing the second impurity region 200b of the substrate 100 may be formed by etching a portion of the first interlayer insulating layer 250 between the bit line structures 226. A contact plug 252 and a landing pad 254 may be formed to fill an inside of the contact hole. An insulating pattern 256 may be formed between landing pads 254.

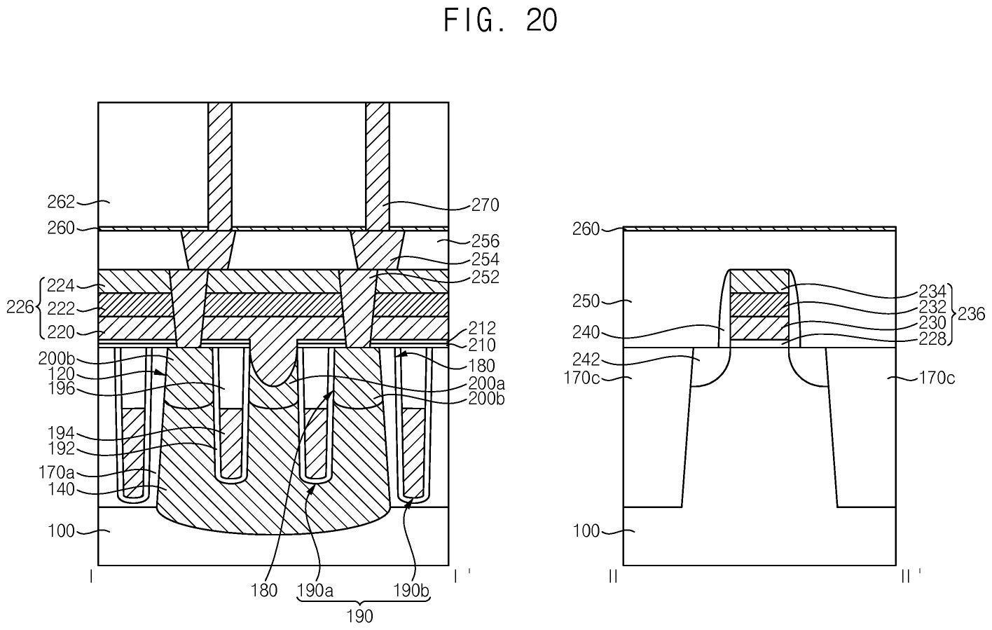

Referring to FIG. 20, an etching stop layer 260 may be formed on the first interlayer insulating layer 250, the landing pad 254, and the insulating pattern 256. The etching stop layer 260 may include, for example, silicon nitride, silicon oxynitride, and the like.

A mold layer 262 may be formed on the etching stop layer 260. The mold layer 262 and the etching stop layer 260 may be anisotropically etched to form holes for forming a capacitor. A top surface of the landing pad 254 may be exposed through bottom surfaces of the holes. The holes may be arranged in a honeycomb structure so as to be located at vertices and a center of a hexagon, respectively.

A lower electrode layer completely filling insides of the holes may be formed on the mold layer 262. According to the exemplary embodiment, the lower electrode layer may include titanium nitride (TiN) or titanium (Ti). Thereafter, the lower electrode layer may be subject to etch-back so as to form a lower electrode 270 inside the hole.

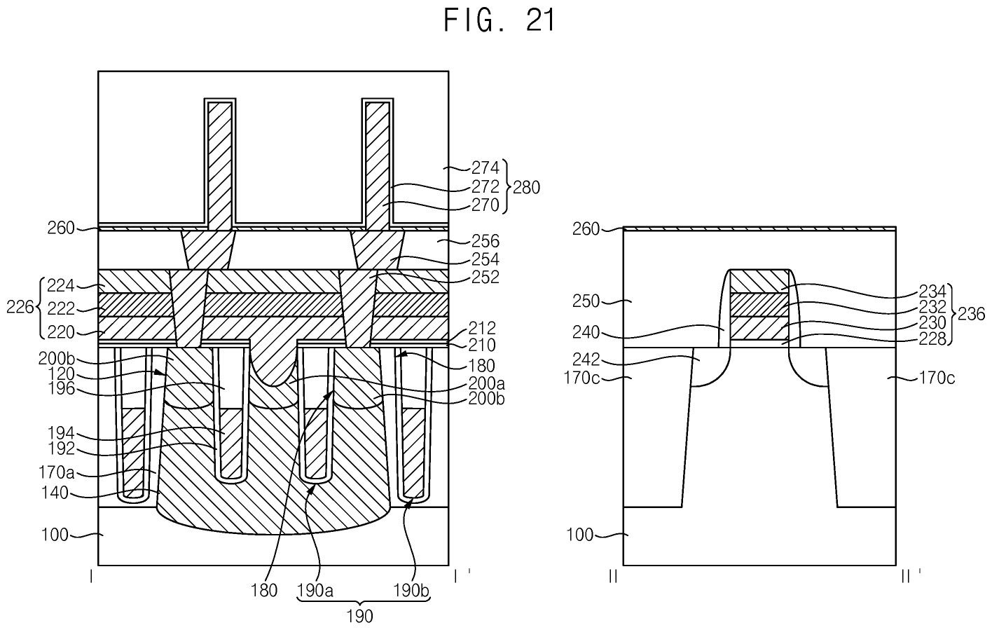

Referring to FIG. 21, the mold layer 262 may be removed. The removal process may include an isotropic etching process, and may include, for example, a wet etching process.

A dielectric layer 272 may be formed on a surface of the lower electrode 270 and the etching stop layer 260. The dielectric layer 272 may include metal oxide having a high dielectric constant. For example, the dielectric layer 272 may include or may be formed of HfO₂, ZrO₂, TiO₂, TaO, or La₂O₃. An upper electrode 274 may be formed on the dielectric layer 272. Therefore, a capacitor 280 including the lower electrode 270, the dielectric layer 272, and the upper electrode 274 may be formed. The capacitor 280 may be electrically connected to the second impurity region 200b.

Through the above process, the DRAM device may be manufactured. The DRAM device may be configured such that the barrier impurity region 140 may be formed on the first and second side wall surfaces of the major axis of the first active pattern 130 in the memory cell region A. Therefore, even when charges stored in the capacitor 280 move to the first active pattern 130 through the landing pad 254 and the contact plug 252, movement and dissipation of the charges to a lower portion of a bottom surface of the first gate structure 190 may be suppressed by the barrier impurity region 140. Thus, a malfunction of the memory cell of the DRAM device may be reduced.

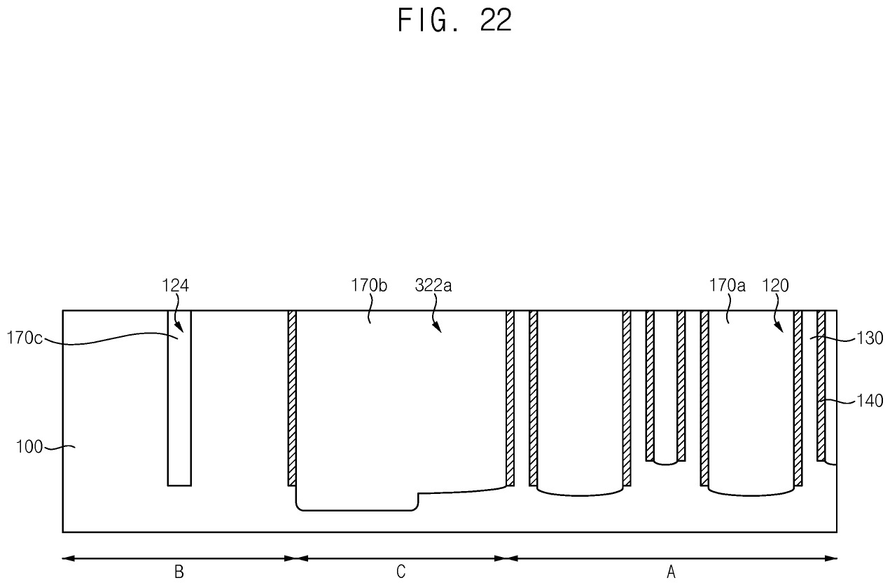

FIG. 22 is a sectional view showing an active pattern and device isolation patterns of a DRAM device in a memory cell region, a core-peripheral region, and a boundary region according to exemplary embodiments.

A DRAM device that will described below may have the same structure as the DRAM device described with reference to FIGS. 1 and 2. However, there is only a difference in a shape of the step of the bottom surface of the second trench in the boundary region. Therefore, the step of the bottom surface of the second trench in the boundary region will be mainly described.

Referring to FIG. 22, a bottom surface of a second trench 322a may have a step without being flat. The second trench 322a may include a first region that is adjacent to the memory cell region A in the boundary region C, and a second region that is adjacent to the core-peripheral region B in the boundary region C.

According to the exemplary embodiment, in the boundary region C, a bottom surface of the first portion may have a first step, and a bottom surface of the second portion may have a second step that is lower than the first step. Therefore, the bottom surface of the second trench 322a may have a step shape when viewed in a sectional view.

The DRAM device shown in FIG. 22 may be formed by a method that is similar to the method for manufacturing the DRAM device described with reference to FIGS. 8 to 21. However, a position of the etching mask may be partially changed.

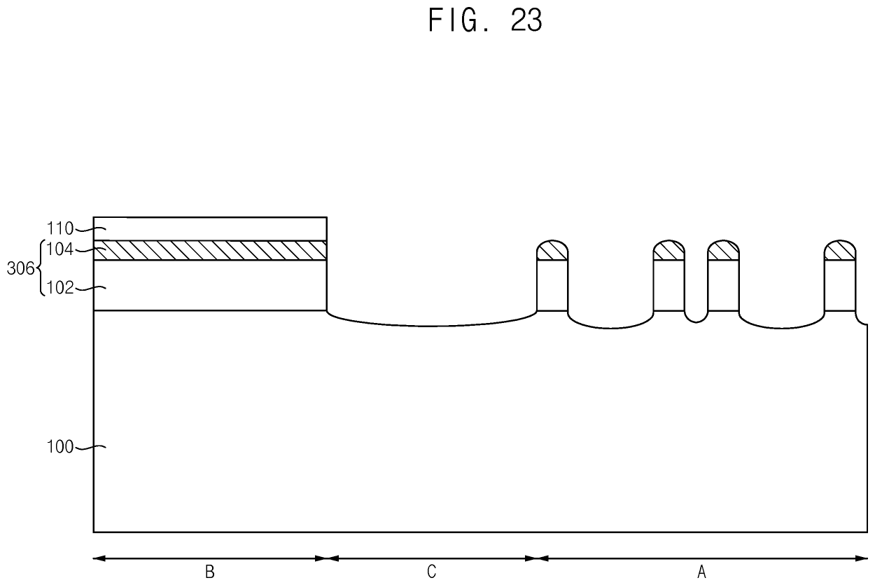

FIGS. 23 to 26 are sectional views showing a method for manufacturing a DRAM device according to exemplary embodiments.

Referring to FIG. 23, a substrate 100 including a memory cell region A, a core-peripheral region B, and a boundary region C between the memory cell region A and the core-peripheral region B may be provided. A mask pattern structure 306 for forming a trench may be formed on the substrate 100.

The mask pattern structure 306 formed on the substrate 100 in the memory cell region A may cover a region in which a first active pattern is to be formed. For example, a region between mask pattern structures 306 may be a region in which a first device isolation pattern is to be formed. The mask pattern structure 306 may completely cover the substrate 100 in the core-peripheral region B. In addition, the mask pattern structure 106 may expose all of the substrate 100 in the boundary region C.

Thereafter, a first photoresist pattern 110 covering the mask pattern structure 306 on the core-peripheral region may be formed. The first photoresist pattern 110 may not be formed on the substrate 100 on the boundary region C and the memory cell region A and the mask pattern structure 306.

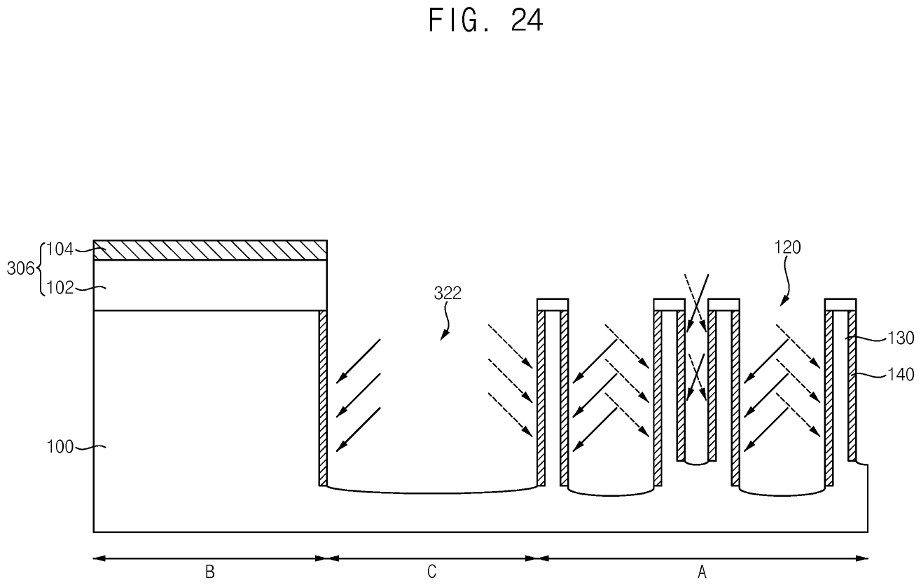

Referring to FIG. 24, an upper portion of the substrate 100 may be etched by using the mask pattern structure 306 and the first photoresist pattern 110 as an etching mask to form trenches.

Through the above process, a first trench 120 and a first active pattern 130 may be formed in the memory cell region A. A preliminary second trench 322 may be formed in the boundary region C. In this case, since the substrate 100 in the core-peripheral region B is covered by the mask pattern structure 306 and the first photoresist pattern 110, a trench may not be formed in the core-peripheral region B.

Thereafter, first and second side wall surfaces of a major axis of the first active patterns 130 in the memory cell region A may be selectively doped with a first impurity so as to form a barrier impurity region 140.

In this case, the barrier impurity region 140 may also be formed on a side wall of a preliminary second trench 322 that is adjacent to the core-peripheral region B.

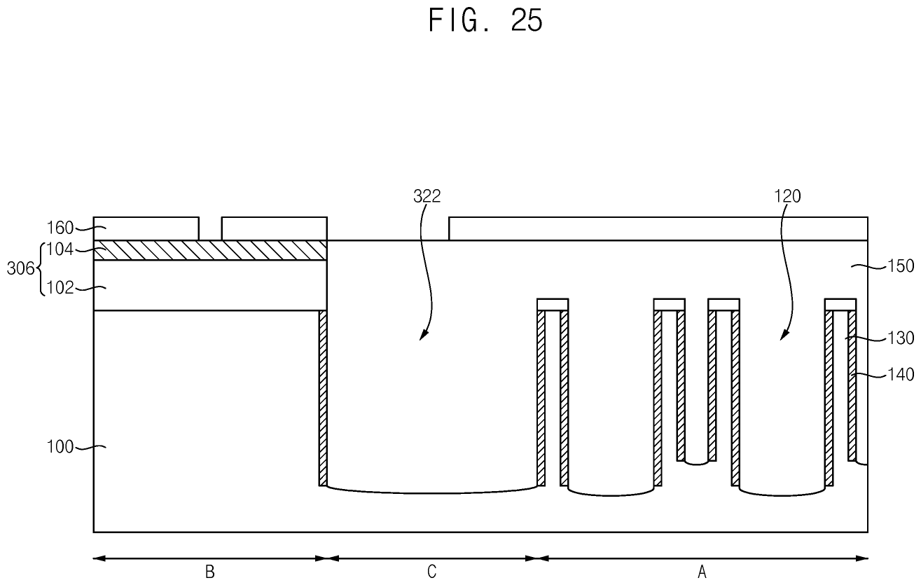

Referring to FIG. 25, a preliminary sacrificial layer may be formed to completely fill the first trench 120 and the preliminary second trench 322. Thereafter, a sacrificial layer 150 may be formed by planarizing the preliminary sacrificial layer so that a top surface of the mask pattern structure 306 may be exposed.

A second photoresist layer may be formed to cover the mask pattern structure 306 and the sacrificial layer 150. The second photoresist layer may be patterned through a photolithography process to form a second photoresist pattern 160.

The second photoresist pattern 160 may cover the sacrificial layer 150 on the memory cell region A and a portion of the boundary region C that is adjacent to the memory cell region A. The sacrificial layer 150 on the remaining portion of the boundary region C and the mask pattern structure 306 may be exposed by the second photoresist pattern.

In addition, the second photoresist pattern 160 may selectively expose a region of the substrate in the core-peripheral region B where a third device isolation pattern is to be formed. For example, the second photoresist pattern 160 may completely cover a region of the core-peripheral region B corresponding to the active region.

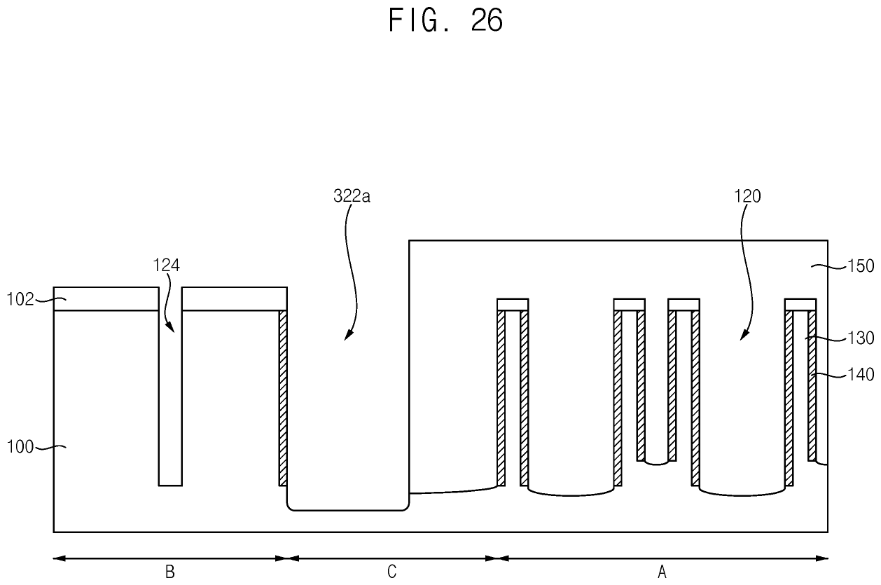

Referring to FIG. 26, the mask pattern structure 306 and the sacrificial layer 150 may be anisotropically etched by using the second photoresist pattern 160 as an etching mask.

Subsequently, the substrate 100 disposed under the mask pattern structure 306 in the core-peripheral region B may be etched to form a third trench 124. A region of the substrate 100 in the core-peripheral region B in which the third trench 124 is not formed may be provided as an active region.

In addition, according to the etching process, the sacrificial layer 150 in the boundary region C and the substrate 100 under the sacrificial layer 150 may be additionally etched to form a second trench 322a in the boundary region C.

The second trench 322a may include a portion pre-etched in an etching process for forming the first trench 120, and a portion etched in an etching process for forming the third trench 124.

As described above, a bottom surface of the second trench 322a may have a step without being flat. According to the exemplary embodiment, the second trench 322a may include a first region that is adjacent to the memory cell region Ain the boundary region C, and a second region that is adjacent to the core-peripheral region B in the boundary region C.

According to the exemplary embodiment, in the boundary region C, a bottom surface of the first portion may have a first step, and a bottom surface of the second portion may have a second step that is lower than the first step. Therefore, the bottom surface of the second trench 322a may have a step shape when viewed in a sectional view.

Thereafter, the DRAM device may be manufactured by performing the same process as described with reference to FIGS. 16 to 21.

What is claimed is:

1. A semiconductor device comprising:
a substrate extending in a first direction and a second direction perpendicular to the first direction;
a first active pattern included in an upper portion of the substrate in a memory cell region, and having an isolated shape extending in a third direction that is oblique to the first direction, the third direction being a major axis direction of the first active pattern;
a first device isolation pattern formed inside a first trench included in the substrate in the memory cell region, and covering a side wall of the first active pattern;
a first gate structure formed inside a gate trench extending in the first direction on upper portions of the first active pattern and the first device isolation pattern;
a barrier impurity region selectively formed only on surfaces of both side walls of the major axis of the first active pattern; and
first and second impurity regions on the upper portion of the first active pattern that is adjacent to both sides of the first gate structure.

2. The semiconductor device of claim 1, wherein the barrier impurity region includes an impurity having a negative charge when doped to the substrate.

3. The semiconductor device of claim 1, wherein an impurity included in the barrier impurity region includes silicon germanium or fluorine.

4. The semiconductor device of claim 1, wherein the barrier impurity region is not formed on side walls of a minor axis of the first active pattern.

5. The semiconductor device of claim 1, wherein a bottom surface of the barrier impurity region is lower than a bottom surface of the first gate structure.

6. The semiconductor device of claim 1, wherein the barrier impurity region extends from a top surface of the first active pattern to a portion under a bottom surface of the first device isolation pattern.

7. The semiconductor device of claim 1, wherein two first gate structures are spaced apart from each other in one first active pattern, and
one first gate structure is disposed in each of first device isolation patterns contacting both ends of the one first active pattern in the major axis direction.

8. The semiconductor device of claim 1, wherein the first impurity region is located at a central portion of the first active pattern in the major axis direction,
the second impurity region is located at both edges of the first active pattern in the major axis direction, and
the semiconductor device further comprises:
a bit line structure electrically connected to the first impurity region; and
a capacitor electrically connected to the second impurity region.

9. The semiconductor device of claim 1, wherein a second trench is included in the substrate in a boundary region, which makes contact with an edge of the memory cell region,
a second device isolation pattern filling the second trench is provided, and
a bottom surface of the second trench has a step shape without being flat.

10. A semiconductor device comprising:
a substrate including a memory cell region, a core-peripheral region, and a boundary region between the memory cell region and the core-peripheral region;
a first active pattern and a first device isolation pattern, which are formed on an upper portion of the substrate in the memory cell region;
a second device isolation pattern filling a second trench included in the substrate in the boundary region between the memory cell region and the core-peripheral region;
a third device isolation pattern filling a third trench included in the substrate in the core-peripheral region;
a first gate structure formed inside a gate trench extending in a first direction on upper portions of the first active pattern and the first device isolation pattern;
a barrier impurity region selectively formed only on surfaces of both side walls of a major axis of the first active pattern; and
first and second impurity regions on the upper portion of the first active pattern that is adjacent to both sides of the first gate structure,
wherein a bottom surface of the second trench has a step shape without being flat.

11. The semiconductor device of claim 10, wherein the barrier impurity region includes an impurity having a negative charge when doped to the substrate.

12. The semiconductor device of claim 10, wherein an impurity included in the barrier impurity region includes silicon germanium or fluorine.

13. The semiconductor device of claim 10, wherein a bottom surface of the barrier impurity region is lower than a bottom surface of the first gate structure.

14. The semiconductor device of claim 10, wherein the second trench includes:
a first region that is adjacent to the memory cell region in the boundary region;
a second region that is adjacent to the core-peripheral region in the boundary region; and
a third region between the first region and the second region, and
a bottom surface of the third region is lower than a bottom surface of each of the first and second regions.

15. The semiconductor device of claim 10, wherein the second trench includes:
a first region that is adjacent to the memory cell region in the boundary region; and
a second region that is adjacent to the core-peripheral region in the boundary region, and
a bottom surface of the second region is lower than a bottom surface of the first region.

16. The semiconductor device of claim 10, wherein two first gate structures are spaced apart from each other in one first active pattern, and
one first gate structure is disposed in each of first device isolation patterns contacting both ends of the one first active pattern in a major axis direction.

17. The semiconductor device of claim 10, wherein the first impurity region is located at a central portion of the first active pattern in the major axis direction,
the second impurity region is located at both edges of the first active pattern in the major axis direction, and
the semiconductor device further comprises:
a bit line structure electrically connected to the first impurity region; and
a capacitor electrically connected to the second impurity region.

18. A semiconductor device comprising:
a substrate including a memory cell region, a core-peripheral region, and a boundary region between the memory cell region and the core-peripheral region;
a first active pattern and a first device isolation pattern, which are provided on an upper portion of the substrate in the memory cell region;
a second device isolation pattern filling a second trench included in the substrate in the boundary region between the memory cell region and the core-peripheral region;
a third device isolation pattern filling a third trench included in the substrate in the core-peripheral region;
a first gate structure formed inside a gate trench extending in a first direction on upper portions of the first active pattern and the first device isolation pattern;
a barrier impurity region selectively formed only on surfaces of both side walls of a major axis of the first active pattern, and doped with silicon germanium or fluorine;
first and second impurity regions on the upper portion of the first active pattern that is adjacent to both sides of the first gate structure;
a bit line structure electrically connected to the first impurity region; and
a capacitor electrically connected to the second impurity region.

19. The semiconductor device of claim 18, wherein a bottom surface of the barrier impurity region is lower than a bottom surface of the first gate structure.

20. The semiconductor device of claim 18, wherein the barrier impurity region extends from a top surface of the first active pattern to a portion under a bottom surface of the first device isolation pattern.
